(19) United States
(12) Patent Application Publication
(10) Pub. No.: US 2020/0135991 A1
(43) Pub. Date: Apr. 30, 2020

(54) LIGHTING DEVICE AND LIGHTING MODULE

(71) Applicant: Everlight Electronics Co., Ltd., New Taipei City (TW)

(72) Inventors: Chun-Min LIN, New Taipei City (TW); Bo Cheng JIANG, New Taipei City (TW); Shang-Fu KAO, New Taipei City (TW); Yu Ju CHEN, New Taipei City (TW); Jen-hsiung LAI, New Taipei City (TW); Chung Chuan HSIEH, New Taipei City (TW)

(73) Assignee: Everlight Electronics Co., Ltd., New Taipei City (TW)

(21) Appl. No.: 16/667,233

(22) Filed: Oct. 29, 2019

Related U.S. Application Data
(60) Provisional application No. 62/753,252, filed on Oct. 31, 2018.
(60) Provisional application No. 62/795,321, filed on Jan. 22, 2019.

(51) Int. Cl. H01L 33/58; H01L 33/54; H01L 33/50; H01L 33/60; H01L 25/075; H01L 33/62; H01L 33/56; F21K 9/66; H01L 33/48; H01L 25/13; F21K 9/62

(52) U.S. Cl. CPC H01L 33/58; H01L 33/54; H01L 33/507; H01L 33/60; H01L 25/0753; F21Y 2115/10; H01L 33/56; F21K 9/66; H01L 33/486; H01L 25/13; F21K 9/62; H01L 33/62

(57) ABSTRACT

A lighting device is disclosed, including an LED die, a light-transmissive encapsulant and a light-transmissive wall. The light-transmissive encapsulant covers the light-emitting side surfaces and the top surface, and the light-transmissive wall surrounds the light-transmissive encapsulant and covers the side surfaces of the light-transmissive encapsulant. Furthermore, the refractive index of the light-transmissive encapsulant is not greater than the refractive index of the light-transmissive wall. A lighting module is further disclosed, including a circuit substrate and the lighting devices, as described above, which are disposed on the circuit substrate. Therefore, when lights generated from the LED die are transmitted into the light-transmissive wall from the light-transmissive encapsulant, the lights will be deflected towards the lateral direction, thereby increasing the viewing angle of the lighting device.

### CROSS-REFERENCES TO RELATED APPLICATIONS

This application claims priority to U.S. provisional Patent Application No. 62/753,252 filed on Oct. 31, 2018, and U.S. provisional Patent Application No. 62/795,321 field on Jan. 22, 2019, which is hereby incorporated herein by reference in its entirety.

### BACKGROUND OF THE INVENTION

### Field of the Invention

The present invention relates to a lighting device and a lighting module, and more particularly, relates to a lighting device having a large viewing angle and a lighting module using the lighting device.

### Descriptions of the Related Art

As LCD TVs and mobile devices continue to develop towards a low profile, lighting devices, as back-light sources thereof, also need to be miniaturized. Currently, Light Emitting Diode (LED) dies are mainly used as the back-light sources, because LED dies feature a high efficiency, high brightness, a high reliability and a fast response time or the like in addition to a small size. These LED dies are packaged to form lighting devices, and then the lighting devices are arranged intermittently on a substrate. These lighting devices can emit light to optical elements such as a liquid crystal layer, and then images are formed for viewing by users. In addition, to enhance the contrast of the displayed images, the local dimming technology is applied so that the lighting devices that correspond to the black part of the images do not emit light.

In such back-light applications, the number of the lighting devices can be reduced and the optical distance required for mixing the light can also be reduced, if the lighting devices have larger viewing angles. Currently, the lighting devices are often packaged in the form of reflector cups, because the manufacturing technology thereof is mature and the cost thereof is lower. However, the viewing angle of such lighting devices is only about 120 degrees. For this reason, secondary optical designs are required to increase the viewing angle to 140˜160 degrees. That is, the light is diffused through an additional optical lens. However, for light-weight displays, the limited space thereof is not suitable for further installation of the optical lens, which will increase the production cost. However, if no optical lens is disposed, then a large number of lighting devices are needed, which increases the production cost.

Therefore, in the technical field of the lighting device, there are still problems to be solved.

### SUMMARY OF THE INVENTION

An objective of the present invention is to provide a lighting device and a lighting module, and the lighting device may have a larger viewing angle (which may for example be up to 140˜160 degrees), thereby reducing the number required for constituting the lighting module or reduce the optical distance required.

To achieve the aforesaid objective, the lighting device disclosed by the present invention comprises: an LED die, comprising a light-emitting top surface and a plurality of light-emitting side surfaces, the light-emitting top surface is connected with the light-emitting side surfaces; a light-transmissive encapsulant, covering the light-emitting side surfaces and the light-emitting top surface of the LED die, and comprising a plurality of side surfaces connected with each other, a top surface and a bottom surface; and a light-transmissive wall, surrounding the light-transmissive encapsulant and covering the side surfaces of the light-transmissive encapsulant, wherein a refractive index of the light-transmissive encapsulant is not greater than a refractive index of the light-transmissive wall.

According to an embodiment of the present invention, an angle may be defined between the side surface and the bottom surface, and the angle ranges from 90 degrees to 160 degrees.

According to an embodiment of the present invention, the light-transmissive wall may comprise a filling material for increasing the structural strength, or the light-transmissive encapsulant may comprise a photoluminescence material. Moreover, any of the light-transmissive encapsulant and the light-transmissive wall may include a thermoplastic resin or a thermosetting resin.

According to an embodiment of the present invention, the top surface of the light-transmissive encapsulant may be a concave surface or a flat surface. Moreover, the light-transmissive encapsulant may further comprise a lens. The lens may comprise a concave portion.

According to an embodiment of the present invention, the lighting device may further comprise a reflective layer, wherein the reflective layer is located above the light-emitting top surface of the LED die, and shields the light-emitting top surface in a normal direction of the light-emitting top surface. Moreover, the reflective layer may be disposed on the top surface of the light-transmissive encapsulant or disposed on the light-emitting top surface of the LED die.

According to an embodiment of the present invention, the reflective layer may include a shielding surface, and the shielding surface is not less than the light-emitting top surface of the LED die or not less than the top surface of the light-transmissive encapsulant. The shielding surface may be of a circular shape, an elliptical shape or a polygonal shape. Moreover, the shielding surface may comprise a plurality of light-transmissive regions.

According to an embodiment of the present invention, the light device may further comprise another LED die, and the light-transmissive encapsulant covers a plurality of light-emitting side surfaces and a light-emitting top surface of the another LED die. Moreover, the lighting device may further comprise a lead frame structure or a carrier substrate, the LED die is disposed on the lead frame structure or the carrier substrate and is electrically connected with the lead frame structure or the carrier substrate, while the light-transmissive encapsulant and the light-transmissive wall are disposed on the lead frame structure.

To achieve the aforesaid objective, a lighting module disclosed by the present invention comprises: a circuit substrate and a plurality of lighting devices as described above, and the lighting devices are disposed on the circuit substrate and electrically connected with the circuit substrate.

According to an embodiment of the present invention, the lighting module may further comprise a light diffuser plate, and the light diffuser plate is disposed above the lighting devices.

According to an embodiment of the present invention, in a normal direction of the light-emitting top surface of the LED die of the lighting device, there is a vertical distance between the light diffuser plate and the circuit substrate, and in a lateral direction that is orthogonal to the normal direction, there is a lateral distance between the lighting devices; and a ratio of the vertical distance to the lateral distance may range from 0.1 to 0.8.

Accordingly, the lighting device and the lighting module of the present invention at least may provide the following benefits:

1. As the refractive index of the light-transmissive encapsulant is not greater than the refractive index of the light-transmissive wall, the light generated from the LED die will be deflected towards the lateral direction when they are transmitted into the light-transmissive wall from the light-transmissive encapsulant. In this way, the light may be spread laterally, thereby increasing the viewing angle.

2. When the light-transmissive encapsulant includes the lens, the light propagating in the normal direction can be diffused by the lens to further increase the viewing angle.

3. When the reflective layer is disposed above the LED die, the light propagating in the normal direction may be blocked by the reflective layer and then propagate towards the lateral direction to further increase the viewing angle.

4. The process of the light-transmissive wall and the light-transmissive encapsulant may follow the process of the existing reflector-cup package without using special processes, and thus the light-transmissive wall and the light-transmissive encapsulant can have a lower manufacturing cost.

5. Since the lighting devices have larger viewing angles, the lighting module required can be formed with a smaller number of lighting devices. Alternatively, the optical distance (the light-mixing distance) required by these lighting devices can be reduced so that the thickness of the lighting module can also be reduced.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A and FIG. 1B are a cross-sectional view and a perspective view of a lighting device according to a preferred embodiment of the present invention;

FIG. 2A and FIG. 2B are perspective views of a lighting device according to a preferred embodiment of the present invention;

FIG. 3A and FIG. 3B are side views of a lighting device according to a preferred embodiment of the present invention;

FIG. 4 to FIG. 6 are cross-sectional views of a lighting device according to a preferred embodiment of the present invention;

FIG. 7A is a side view of a lighting device according to a preferred embodiment of the present invention;

FIG. 7B and FIG. 8A are perspective views of a lighting device according to a preferred embodiment of the present invention;

FIG. 8B to FIG. 8E and FIG. 8K are cross-sectional views and a side view of a lighting device according to a preferred embodiment of the present invention;

FIG. 8F to FIG. 8J are perspective views of a lighting device according to a preferred embodiment of the present invention;

FIG. 9A and FIG. 9B are front views of a lighting module according to a preferred embodiment of the present invention;

FIG. 9C and FIG. 9D are top views of a lighting module according to a preferred embodiment of the present invention;

FIG. 10A to FIG. 14C are radiation-pattern views (views regarding distribution of angle vs. relative strength) of a lighting device according to a preferred embodiment of the present invention;

FIG. 15A shows light-mixing effects of a conventional lighting module at different optical distances;

FIG. 15B shows light-mixing effects of a lighting module according to a preferred embodiment of the present invention at different optical distances;

FIG. 16A and FIG. 16B show light-spot shapes of a conventional lighting device; and

FIG. 16C and FIG. 16D show light-spot shapes of a lighting device according to a preferred embodiment of the present invention.

### DESCRIPTION OF THE PREFERRED EMBODIMENT

In the following description, specific embodiments of the present invention will be described specifically. However, the present invention may be implemented by embodiments of different forms without departing from the spirit of the present invention, and the scope claimed by the present invention should not be explained as being limited to the embodiments. As shall be appreciated by those of ordinary skill in the art, the technical content recorded in the embodiments may be modified, or substance replacement may be made to part or all of the technical features; and such modification or replacement does not depart from the claims of the patent invention.

Additionally, the technical contents of the above summary can also serve as the technical contents of the embodiments, or as possible modification of the embodiments. In addition, the directions mentioned (such as forward, back, up, down, two sides, internal and external or the like) are relative ones, and may be defined according to the usage status of the lighting device or module rather than suggesting or indicating that the lighting device or module should have a specific direction, be constructed or operated by a specific direction; and therefore, the directions should not be construed as a limitation of the present invention.

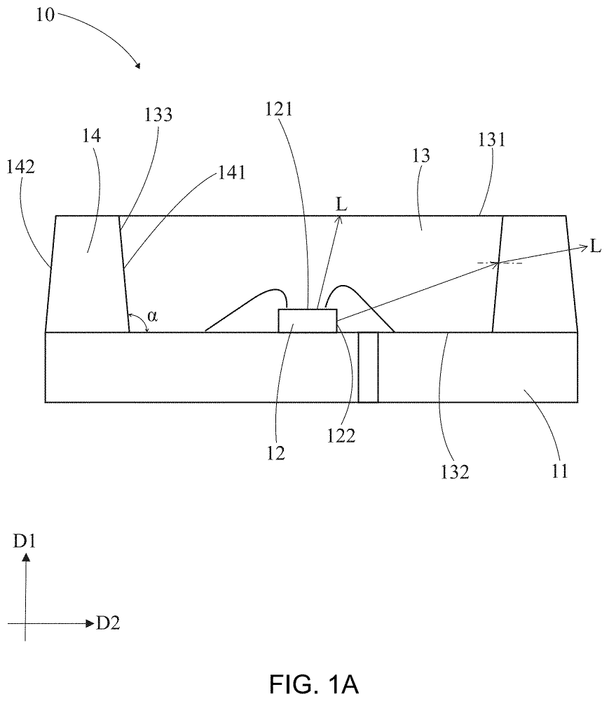

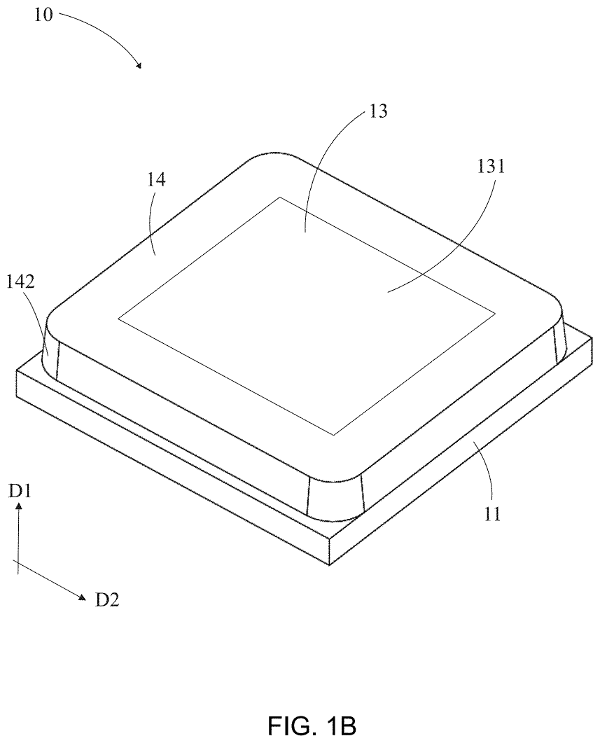

Please refer to FIG. 1A and FIG. 1B, which are a cross-sectional view and a perspective view of a lighting device 10 according to a preferred embodiment of the present invention. The lighting device 10 may serve as a source of light for illumination, instruction, vehicle use, back light or display, to provide light irradiation at a broad angle (broad range). The lighting device 10 may include a lead frame structure 11, an LED die 12, a light-transmissive encapsulant 13 and a light-transmissive wall 14, and technical contents of the elements are explained in sequence as follows.

The lead frame structure 11 comprises at least two conductive frames separated from each other, may have a shape of plate, may have some grooves or through-holes or the like, and is usually made of a metal material, a metal alloy or a metal-plated layer of a good conductivity. The LED die 12 may be a horizontal LED die, a vertical LED die, a flip-chip LED die, a high-voltage LED die or an AC serial-parallel die, and a horizontal LED die is taken as an example of this embodiment. In appearance, the LED die 12 comprises a light-emitting top surface 121 and a plurality of light-emitting side surfaces 122, and the light-emitting top surface 121 is connected with the light-emitting side surfaces 122. That is, the light-emitting side surfaces 122 are respectively connected to at least one side of the light-emitting top surface 121, e.g., four sides (if the light-emitting top surface 121 is of a rectangular shape, then there are four light-emitting side surfaces 122). The light-emitting top surface 121 is defined with a normal direction D1 and a lateral direction D2 that is perpendicular to the normal direction D1, and the light-emitting side surface 122 may be perpendicular to the lateral direction D2. The light L emitted from the semiconductor material within the LED die 12 may be emitted from the light-emitting top surface 121 and the light-emitting side surfaces 122, and the LED die 12 has a configuration of multiple-surface emitting, e.g., a configuration of 5-surface emitting.

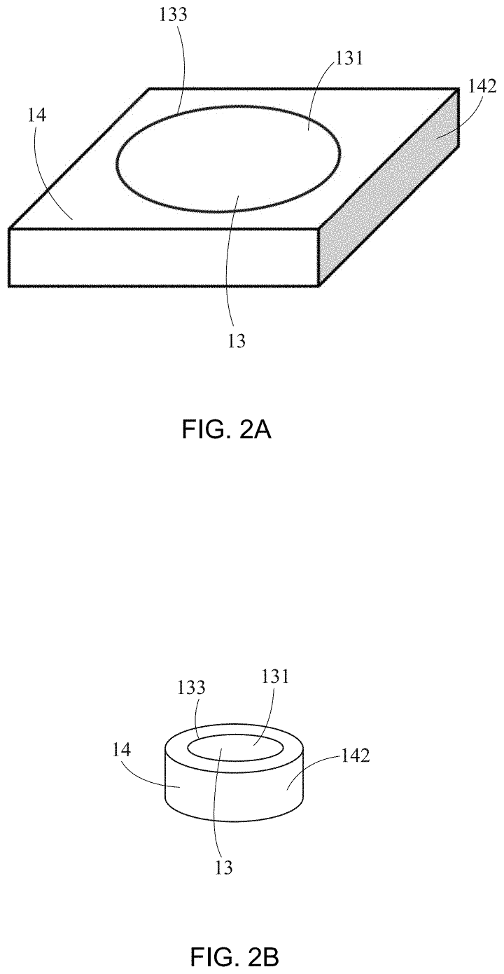

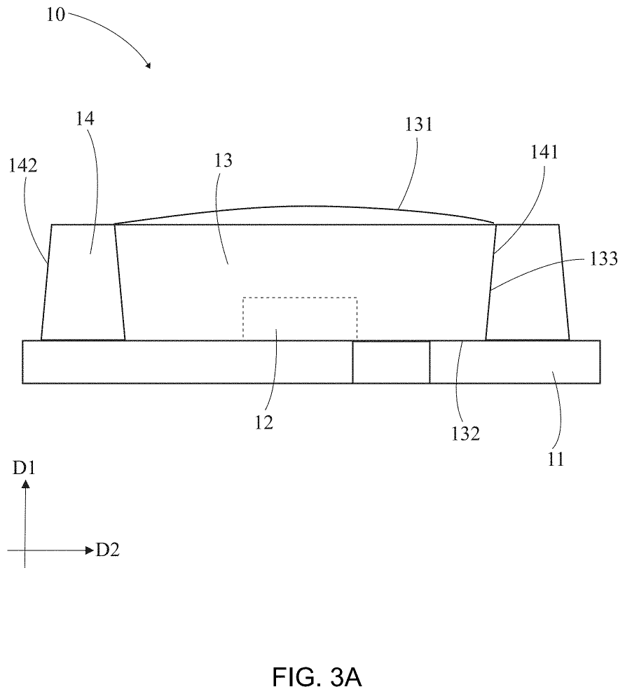

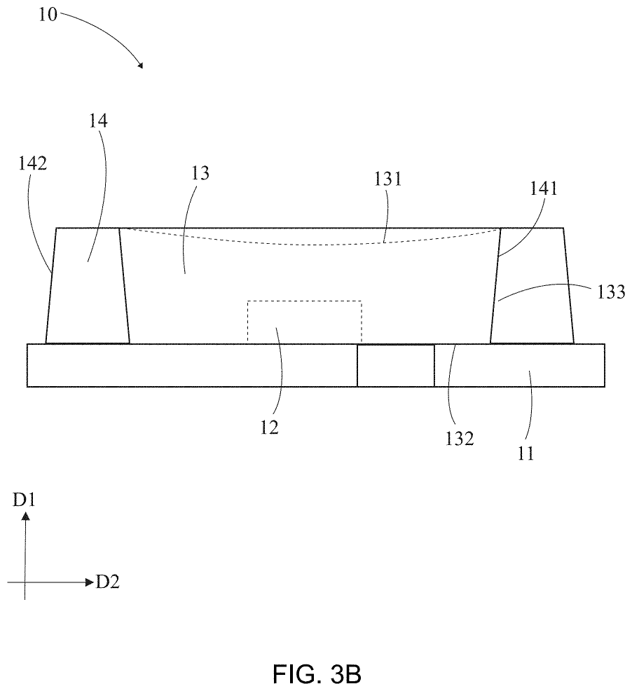

The LED die 12 is disposed on the lead frame structure 11, and the LED die 12 is electrically connected with the lead frame structure 11 (the first and second electrodes of the LED die 12 may be respectively connected with the first and second conductive supports of the lead frame structure 11, e.g., electrically connected by wire bonding). The light-transmissive encapsulant 13 and the lead frame structure 11 are used together to package and protect the LED die 12, thereby avoiding or reducing the contact of the LED die 12 or other elements with moisture or the like in the environment. Therefore, the light-transmissive encapsulant 13 is disposed and formed on the lead frame structure 11, and covers the light-emitting top surface 121 and the light-emitting side surfaces 122 of the LED die 12. The light-transmissive encapsulant 13 may directly contact with the light-emitting top surface 121 and the light-emitting side surfaces 122. In appearance, the light-transmissive encapsulant 13 comprises a top surface 131, a bottom surface 132 and a plurality of side surfaces 133. In the normal direction D1, the top surface 131 is parallel with the bottom surface 132 and is also parallel with the light-emitting top surface 121, and the side surfaces 133 are connected with the top surface 131 and the bottom surface 132 along edges of the top surface 131 and the bottom surface 132. If the top surface 131 and the bottom surface 132 are of a rectangular shape (as shown in FIG. 1B), then the side surface 133 may be a flat surface; if the top surface 131 or the bottom surface 132 is of a circular or elliptical shape (as shown in FIG. 2A or FIG. 2B), then the side surface 133 is a curve surface, and in this aspect, there is one side surface 133. Additionally, the top surface 131 may be a flat surface, a convex surface (as shown in FIG. 3A) or a concave surface (as shown in FIG. 3B).

Moreover, the top surface 131 is larger than or equal to the bottom surface 132 so that the side surface 133 is vertical or inclined relative to the bottom surface 132. In other words, an angle α is defined between the side surface 133 and the bottom surface 132, and the angle α may range from 90 degrees to 160 degrees. The angle α is mainly related to the viewing angle to be described later.

The light-transmissive wall 14 is also disposed and formed above the lead frame structure 11 to make the light L deflect towards the lateral direction D2. The light-transmissive wall 14 surrounds the light-transmissive encapsulant 13 and further covers the side surface 133 of the light-transmissive encapsulant 13. Additionally, the light-transmissive encapsulant 13 and the light-transmissive wall 14 may partially cover the lead frame structure 11 to increase the connection with the lead frame structure 11. In the process, the light-transmissive wall 14 may first be cured and formed on the lead frame structure 11 to form a groove, then steps of die bonding and wire bonding of the LED die 12 are performed within the groove, and next the light-transmissive encapsulant 13 is formed within the groove surrounded by the light-transmissive wall 14 to cover the LED die and the wire bonding. Therefore, an inclined internal side surface 141 of the light-transmissive wall 14 corresponds to the side surface 133 of the light-transmissive encapsulant 13. An external side surface 142 of the light-transmissive wall 14 may be an inclined or vertical flat surface (as shown in FIG. 1A or FIG. 2A) or a curve surface (as shown in FIG. 2B), i.e., the light-transmissive wall 14 is a circular body. Additionally, if the top surface 131 of the light-transmissive encapsulant 13 is a convex surface (as shown in FIG. 3A), then the top surface 131 may be higher than the top surface of the light-transmissive wall 14 by 0.1 mm to 1.0 mm, and preferably be 0.2 mm to 0.7 mm.

The overall refractive index (n1) of the light-transmissive encapsulant 13 is not greater than the overall refractive index (n2) of the light-transmissive wall 14, i.e., n1 is less than or equal to n2 (n1≤n2). As a result, according to the refractive law, the light L will be deflected towards the normal of the interface when the light L is transmitted into the light-transmissive wall 14 from the light-transmissive encapsulant 13 so that more of the light L will propagate towards the lateral direction D2. As a result, the light L that is emitted from the lighting device 10 in the normal direction D1 will become less, and the light L that is emitted from the lighting device 10 in the lateral direction D2 will become more. If the viewing angle is defined with Full Width at Half Maximum (FWHM) of the radiation pattern, then the light device 10 may have a larger viewing angle as compared to the case with no light-transmissive wall 14 (or where the refractive index of the light-transmissive wall 14 is less than the refractive index of the light-transmissive encapsulant 13).

Preferably, the refractive index n1 is less than the refractive index n2, e.g., the refractive index n1 is 1.4 to 1.5, and the refractive index n2 is 1.4 to 1.6. More preferably, the refractive index n1 is 1.45, and the refractive index n2 is 1.55 so that the diffusing effect of the light L is better. The light-transmissive encapsulant 13 and/or the light-transmissive wall 14 may be made of a thermoplastic resin or a thermosetting resin, e.g., Phenylpropanolamine (PPA), Polycyclohexylenedimethylene terephthalate (PCT), Sheet moulding compound (SMC), Epoxy Molding Compound (EMC), Unsaturated Polyester (UP), Polycarbonate (PC), polyethylene (PE), polyethylene terephthalate (PET), Cyclic olefin copolymers (COC) or the like.

Preferably, the height of the light-transmissive wall 14 may be the same as the height of the light-transmissive encapsulant 13, or the height of the light-transmissive wall 14 is slightly greater than the height of the light-transmissive encapsulant 13 so that the light-transmissive wall 14 completely covers the side surface 133 of the light-transmissive encapsulant 13 and the light L passing through each place of the side surface 133 will be deflected towards the lateral side D2. Due to variable or variance of the process, the light-transmissive wall 14 that is slightly higher may cover the periphery of the top surface 131 of the light-transmissive encapsulant 13. Moreover, the viewing angle may also be increased if the light-transmissive wall 14 only covers the lower part of the side surface 133 (not shown). In addition to adjusting the viewing angle by the difference in refractive indexes between the light-transmissive wall 14 and the light-transmissive encapsulant 13 or the inclining angle, the viewing angle can also be adjusted when the top surface 131 of the light-transmissive encapsulant 13 is a convex surface or a concave surface (as shown in FIG. 3A and FIG. 3B). In other words, the top surface 131 of the light-transmissive encapsulant 13 may form a concave lens or a convex lens, i.e., the light-transmissive encapsulant 13 comprises a lens that is formed integrally with other parts. Moreover, the top surface 131 of the light-transmissive encapsulant 13 may also be textured so that the light L is deflected to increase the viewing angle. In an embodiment, the light-transmissive wall 14 may be slightly lower than the light-transmissive encapsulant 13, thereby achieving the effect of increasing the viewing angle.

Other preferred embodiments of the present invention will be described hereinafter, the same parts in the technical contents of the embodiments will be omitted or simplified from the description, and different parts shall be applied to other embodiments (unless there is obvious conflict or incompatibility in the technology).

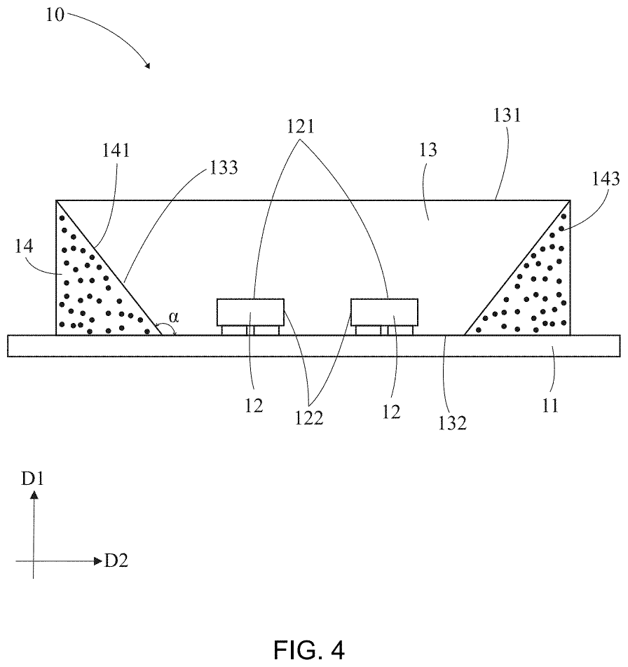

In an embodiment shown in FIG. 4, the lighting device 10 comprises another LED die 12, i.e., the lighting device 10 comprises a plurality of LED dies 12. The another LED die 12 is disposed on the lead frame structure 11, and the light-emitting top surface 121 and the light-emitting side surface 122 thereof are also covered by the light-transmissive encapsulant 13. The light-emitting strength of the lighting device 10 may be larger by comprising more LED dies 12. Additionally, these LED dies 12 are flip-chip dies, and they may also be horizontal LED dies, vertical LED dies, high-voltage LED dies or AC serial/parallel dies.

Moreover, in order to increase the structural strength of the light-transmissive wall 14, the light-transmissive wall 14 may further comprise a filling material 143 which is mixed in the resin material of the light-transmissive wall 14. The filling material 143 may be transparent or semi-transparent, and may also be powder, ball or the like that have tiny particle sizes, so the filling material 143 will not block the light from passing therethrough (will not make the light-transmissive wall 14 a reflective wall). The filling material 143 may also be a glass fiber or oxide (e.g., SiO₂ or TiO₂) or the like. The filling material 143 may also be used to adjust the overall refractive index of the light-transmissive wall 14.

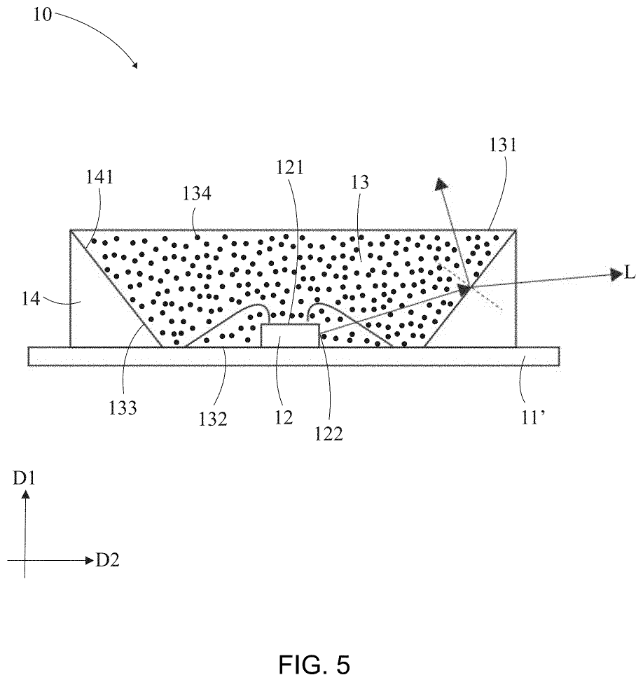

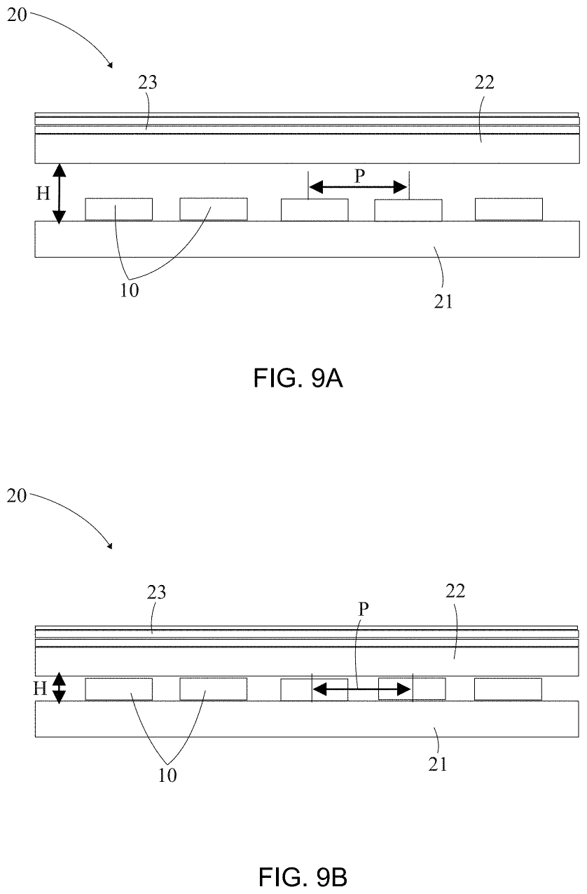

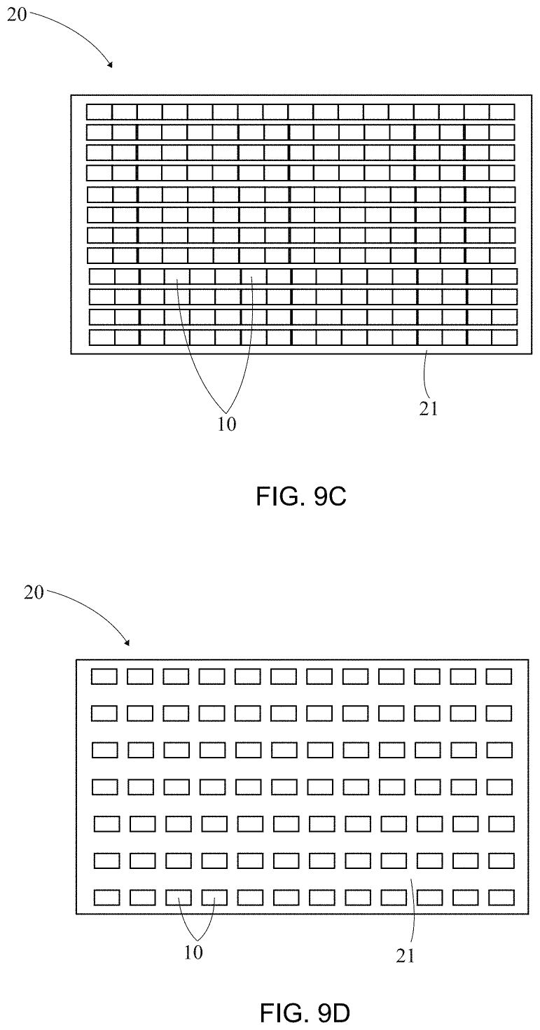

In an embodiment shown in FIG. 5, the lighting device 10 comprises a carrier substrate 11′ to replace the lead frame structure 11 of the above embodiments. More specifically, the carrier substrate 11′ is a substrate made of plastic, ceramic or metal, and it has an insulation layer and a circuit layer formed thereon (not shown). The LED die 12, the light-transmissive encapsulant 13 and the light-transmissive wall 14 may be disposed on the carrier substrate 11′, and positive and negative electrodes of the LED die 12 are further electrically connected to the carrier substrate 11′ (the first circuit layer and the second circuit layer). Furthermore, the carrier substrate 11′ can be large enough so that an assembly of a plurality of “LED dies 12, light-transmissive encapsulants 13 and light-transmissive walls 14” can be formed thereon to form a lighting module similar to that later shown in FIG. 9A to FIG. 9D. On the other hand, the light-transmissive encapsulant 13 may comprise a photoluminescence material 134, such as paint, dye, fluorescent powder, quantum-dot fluorescent powder or the like, which is mixed in a resin material of the light-transmissive encapsulant 13. The photoluminescence material 134 may generate a light of another wavelength (i.e. color) when it is radiated by the light L of the LED die 12. If the LED die 12 is a blue-light die which can emit blue light and the photoluminescence material 134 may absorb part of the blue light and generate yellow light, the lighting device 10 can generate white light (the remaining blue light that is not absorbed by the photoluminescence material is mixed with the yellow light generated by the photoluminescence material to generate the white light). Additionally, the photoluminescence material 134 can also adjust the overall refractive index of the light-transmissive encapsulant 13.

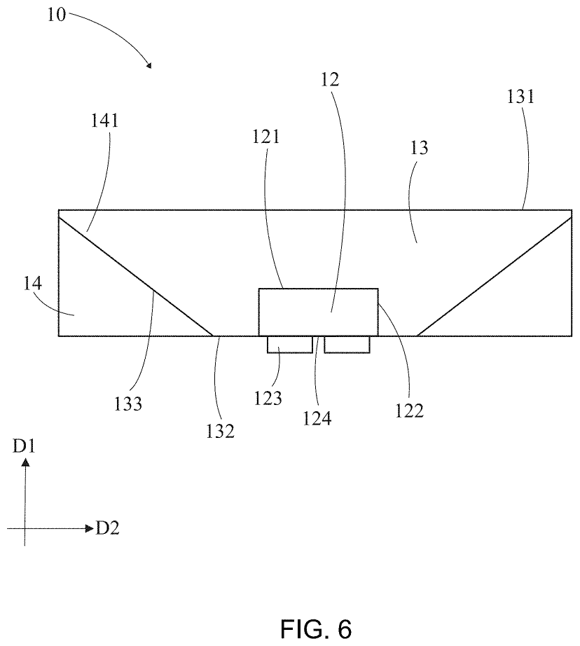

In an embodiment shown in FIG. 6, the lighting device 10 may not comprise the lead frame structure 11 or the carrier substrate 11′, i.e., the lighting device 10 is a chip-scale package (CSP) without a frame or substrate. Electrodes 123 (e.g., positive and negative electrodes) of the LED die 12 within the lighting device 10 may be exposed to the outside of the light-transmissive encapsulant 13, and the bottom surface 124 of the LED die 12 may also be exposed to the outside of the light-transmissive encapsulant 13. The bottom surface 124 is opposite to the light-emitting top surface 121 and is connected with the light-emitting side surface 122.

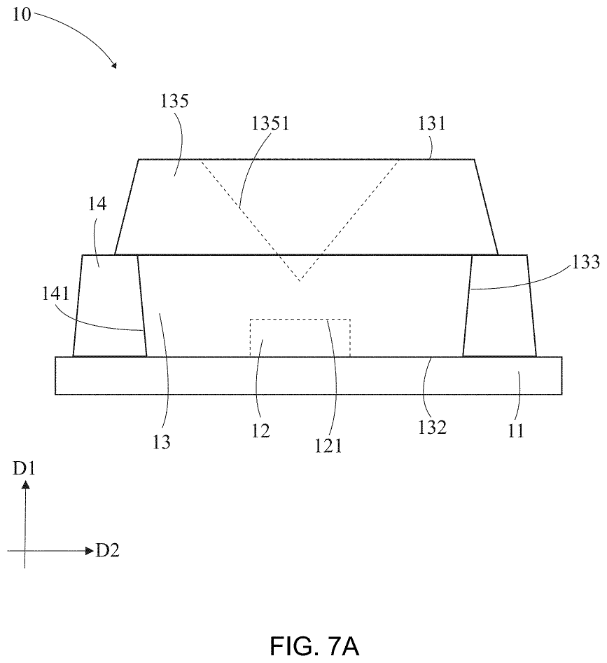

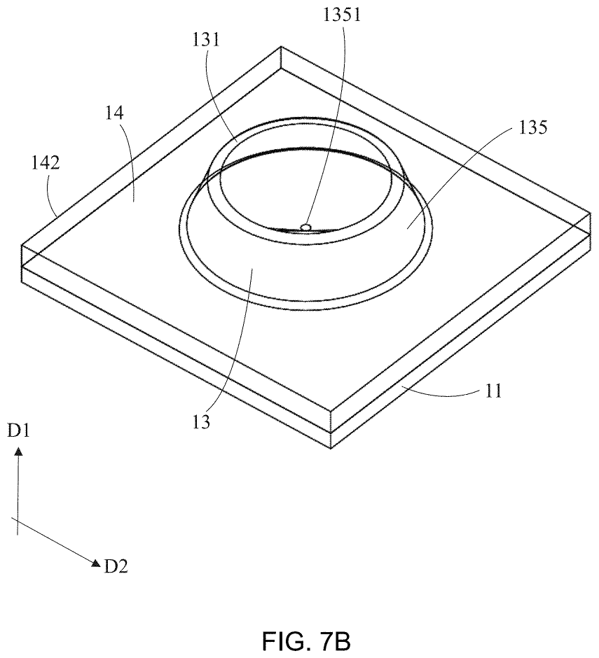

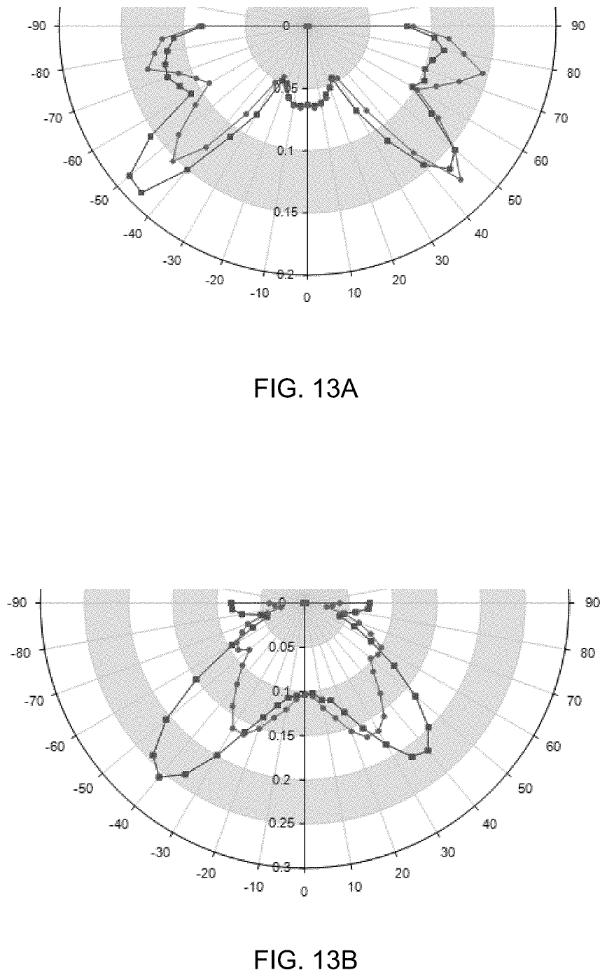

In an embodiment shown in FIG. 7A and FIG. 7B, the light-transmissive encapsulant 13 of the lighting device 10 may comprise a lens 135, and the lens 135 is higher than the light-transmissive wall 14, so the lens 135 is not surrounded or shielded by the light-transmissive wall 14. The lens 135 may optionally extend to the top surface of the light-transmissive wall 14. The top surface 131 of the light-transmissive encapsulant 13 is the top surface of the lens 135. The lens 135 further comprises a concave portion 1351, and the concave portion 1351 recesses downward towards the LED die 12 from the top surface 131 to form a tapered groove. A sharp point (apex) of the concave portion 1351 may be located on an optical axis of the lens 135, and may correspond to a center of the light-emitting top surface 121 of the LED die 12. Air or a material having a low refractive index (i.e., a refractive index lower than that of the light-transmissive encapsulant 13) exists on the concave portion 1351 so that the light of the LED die 12 will be deflected towards the lateral direction D2 when it passes through the concave portion 1351 and then emitted to the outside of the lens 135, thereby reducing the light emission in the normal direction D1. Accordingly, the lighting device 10 can achieve a larger viewing angle or a special radiation pattern (as shown in FIG. 13A and FIG. 13B described later).

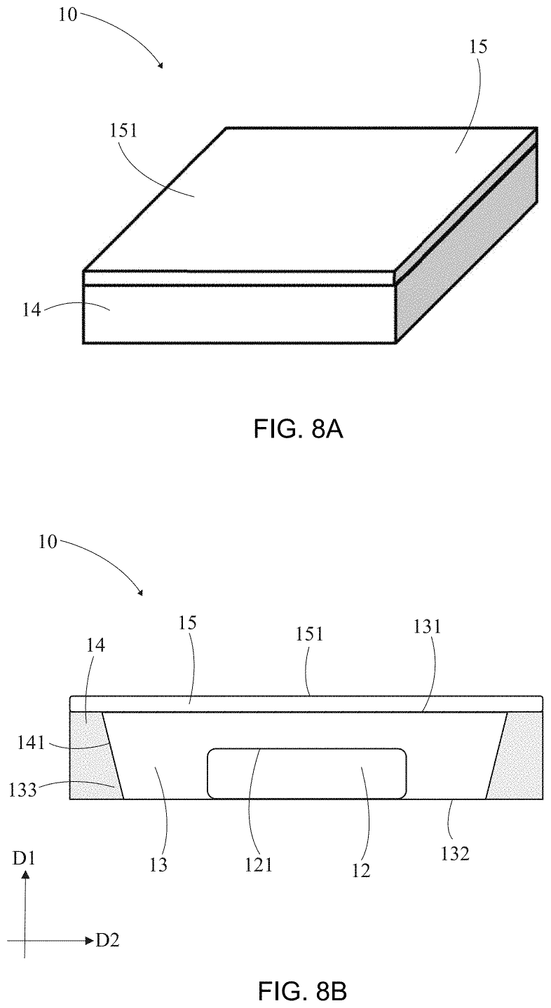

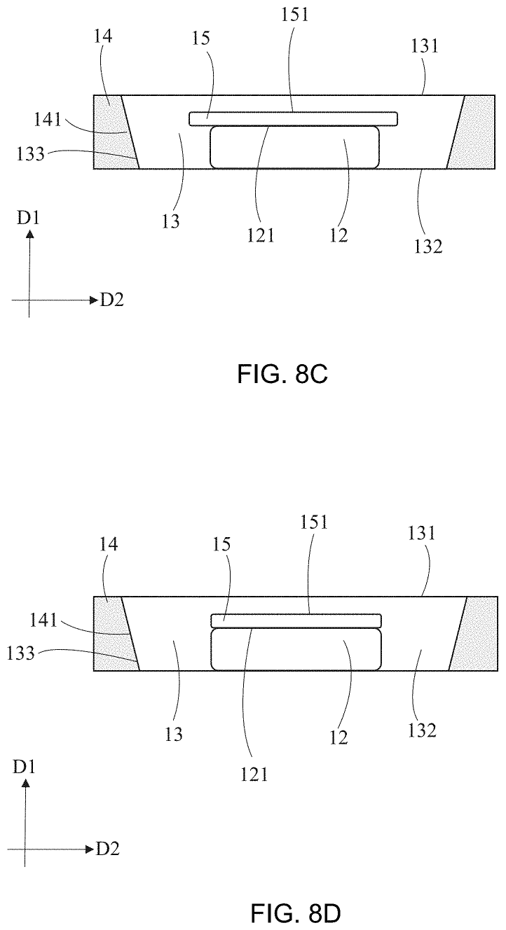

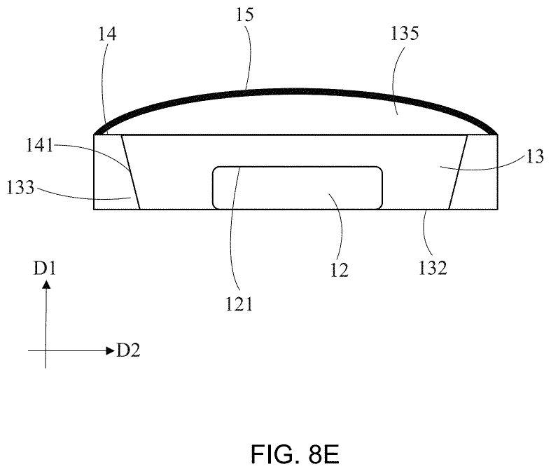

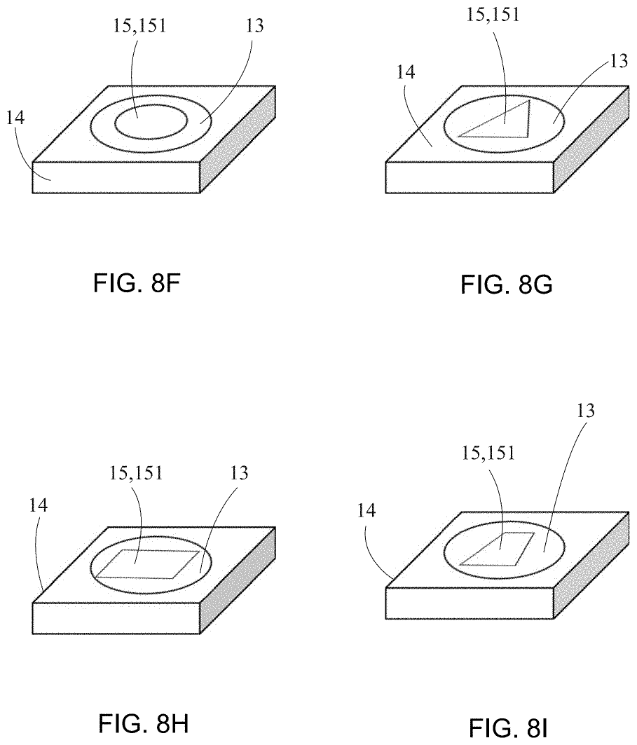

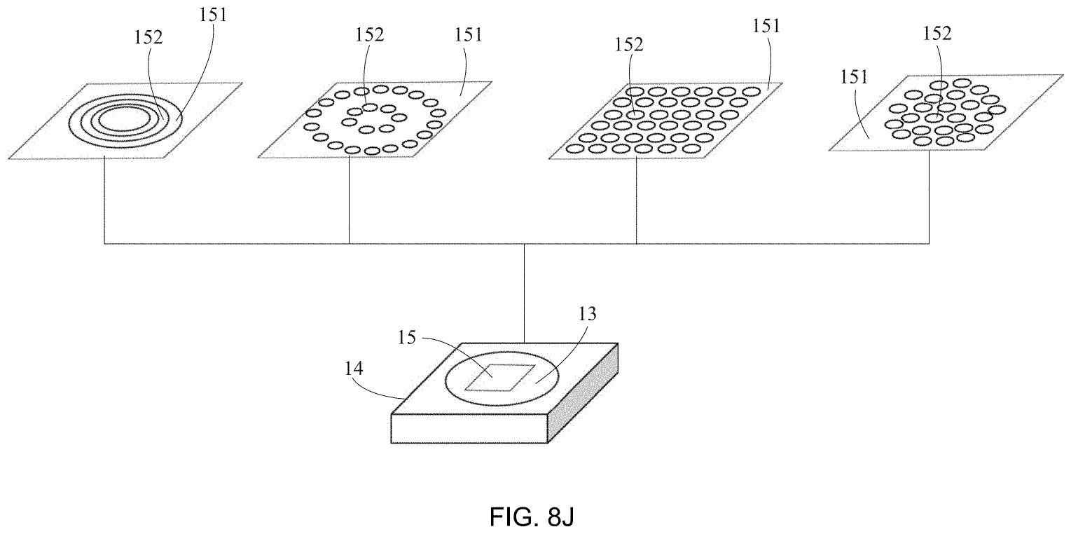

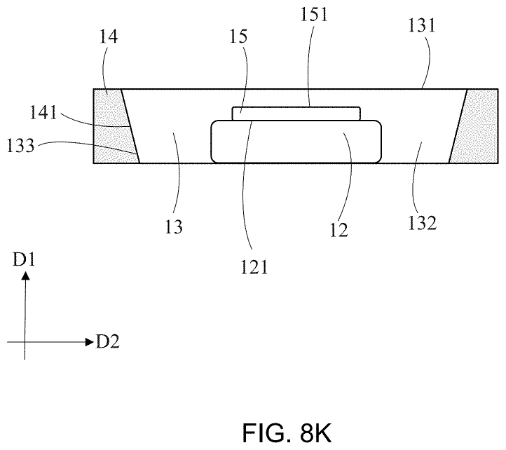

In an embodiment shown in FIG. 8A and FIG. 8B, the lighting device 10 further comprises a reflective layer 15, the reflective layer 15 is located above the light-emitting top surface 121 of the LED die 12 and shields the light-emitting top surface 121 in the normal direction D1. Similar to the concave portion 1351, the reflective layer 15 is used to reduce the light emission in the normal direction D1, but the reflective layer 15 blocks the light so that the light is hard to be emitted upward. The reflective layer 15 may be formed by a metal or non-metal material, and the reflective ratio thereof for the light of the LED die 12 is preferably larger than 70%, and more preferably, is 85% to 98% (e.g., silver, aluminum or the like).

The reflective layer 15 may be directly disposed on the top surface 131 of the light-transmissive encapsulant 13, and may be fully disposed on the top surface 131 or may be further fully disposed on the top surface of the light-transmissive wall 14. Under such arrangement, a shielding surface 151 comprised in the reflective layer 15 is larger than or equal to (not less than) the top surface 131 of the light-transmissive encapsulant 13 so that all (or most) of the light in the normal direction D1 is reflected by the reflective layer 15 and emitted from the external side surface 142 of the light-transmissive wall 14.

As shown in FIG. 8C and FIG. 8D, the reflective layer 15 may also be directly disposed on the light-emitting top surface 121 of the LED die 12, and the shielding surface 151 thereof is larger than or equal to the light-emitting top surface 121. In this way, the light can only be emitted to the light-transmissive encapsulant 13 from the light-emitting side surface 122 of the LED die 12. Then, part of the light emitted from the light-emitting side surface 122 might still be emitted from the top surface 131 of the light-transmissive encapsulant 13. As shown in FIG. 8K, the shielding surface 151 of the reflective layer 15 may also be less than the light-emitting top surface 121, so the light may still be emitted from the part of the light-emitting top surface 121 that is not shielded.

In the process, the reflective layer 15 is first formed on the LED die 12, and then the light-transmissive encapsulant 13 is formed to cover the reflective layer 15 and the LED die 12, and the light-transmissive encapsulant 13 does not directly contact with the light-emitting top surface 121 of the LED die 12. Further as shown in FIG. 8E, if the light-transmissive encapsulant 13 comprises a lens 135, then the reflective layer 15 may be disposed on the lens 135 in a domed form. On the other hand, relative to the light-transmissive encapsulant 13 or the LED die 12, the thickness of the reflective layer 15 is smaller, so the reflective layer 15 is in the form of a film or foil. The reflective layer 15 may also be directly formed on the light-transmissive encapsulant 13 or the LED die 12 via adhesive-dispensing, printing or spraying processes or the like. For example, a non-metal material (boron nitride (BN), titanium dioxide (TiO₂), silicon dioxide (SiO₂)) or a metal material (a scattering or reflective material) is mixed into a resin and then formed on the light-transmissive encapsulant 13 or the LED die 12 via the above process, and the reflective layer 15 is formed after the resin is cured.

As shown in FIG. 8F to FIG. 81, the shielding surface 151 of the reflective layer 15 may be of a circular shape, an elliptical shape or a polygonal (triangular, rectangular, trapezoid, etc.) shape, and may be less than the top surface 131 of the light-transmissive encapsulant 13. In addition, as shown in FIG. 8J, the shielding surface 151 may comprise a plurality of light-transmissive regions 152, and the light-transmissive regions 152 may be of a ring shape or a round-hole shape and may be arranged in a variety of manners. The light can pass through the light-transmissive regions 152 and will not be reflected.

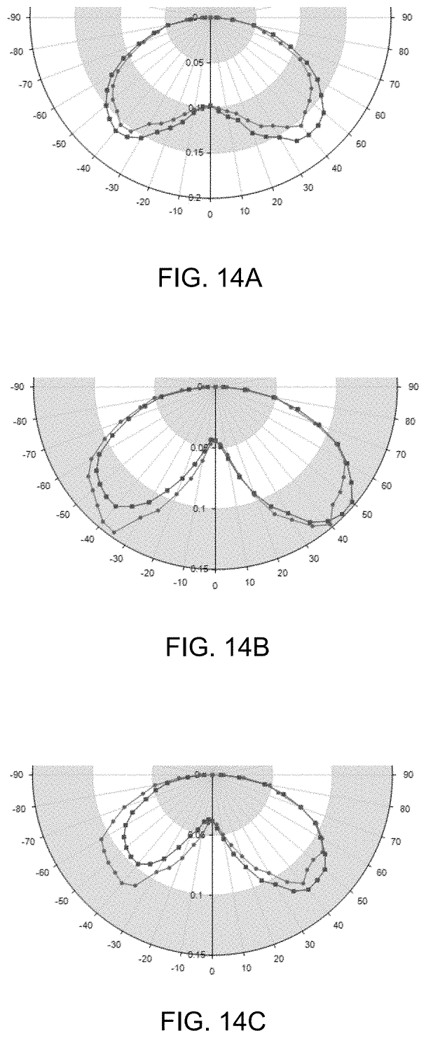

Through the reflective layer 15, the lighting device 10 can have a larger viewing angle or a special radiation pattern (as shown in FIG. 14A to FIG. 14C described later), and different viewing angles or radiation patterns can be obtained by adjusting design parameters such as the size, position, shape and light-transmissive region 152 or the like of the shielding surface 151 of the reflective layer 15.

Referring to FIG. 9A to FIG. 9D, in another preferred embodiment of the present invention, a lighting module 20 is provided, the lighting module 20 comprises a circuit substrate 21 and a plurality of lighting devices 10, and the lighting devices 10 are disposed on the circuit substrate 21 and electrically connected with the circuit substrate 21. Specifically, the circuit substrate 21 is similar to the carrier substrate 11′ shown in FIG. 4, but the circuit substrate 21 has a larger size and the driving circuit thereof can individually light up the lighting devices 10, and the lighting devices 10 may be any lighting device in the above embodiments.

If the lighting module 20 is used as the back-light source of the display, then an light diffuser plate 22 may be further included, and the light diffuser plate 22 is located above the lighting devices 10 so that the light of the lighting device 10 is further diffused and the light is uniformly irradiated on the display panel. Additionally, one or more optical elements 23, e.g., a prism sheet, a dual brightness enhancement film (DBEF) or the like, may be further disposed on the light diffuser plate 22 depending on the situation of application.

In the normal direction D1, there is a vertical distance H between the bottom surface of the light diffuser plate 22 and the top surface of the circuit substrate 21, and in the lateral direction D2, there is a lateral distance P between the lighting devices 10, and the lateral distance P is a line distance between centers of two adjacent lighting devices 10. The vertical distance H corresponds to the optical distance (OD) required for the light mixing, and the lateral distance P corresponds to the density of the lighting devices 10. Because the lighting device 10 can have a larger viewing angle, the vertical distance H may be smaller and the lateral distance P may be larger. Comparing those shown in FIG. 9A and FIG. 9B, when the vertical distance H is reduced, the overall thickness of the lighting module 20 can also be reduced; and comparing those shown in FIG. 9C and FIG. 9D, when the lateral distance P is increased, the number of the lighting devices 10 required by the light module 20 can also be reduced.

The ratio of the vertical distance H to the lateral distance P (H/P) may range from 0.1 to 0.8, which is superior to the ratio of the conventional lighting device (the H/P thereof is usually larger than 1.0). In other words, the lighting module 20 may be thinner or have fewer number of lighting devices 10 as compared to the conventional lighting module, thereby achieving the same light-mixing requirements.

As can be known from the following table showing a measurement result of viewing angles of various types of lighting devices, the light-transmissive wall can increase the viewing angle of the lighting device to be more than 150 degrees, and the arrangement of the reflective layer further increases the viewing angle to be more than 160 degrees. Because the viewing angle is increased to be more than 150 degrees, the ratio of the vertical distance H to the lateral distance P of the lighting module (H/P) is reduced to 0.47 or 0.31.

| | | | | | Top surface of the |
|---|---|---|---|---|---|
| | | Light-emitting | Light-emitting | Light-emitting | light-transmissive |
| | | top surface | top surface | top surface | encapsulant and the |
| | | being larger | being equal | being smaller | light-transmissive |
| | Without | than the | to the | than the | wall being equal |
| | reflective | shielding | shielding | shielding | to the shielding |
| Types | layer | surface | surface | surface | surface |
| Angle | 150.9/158.4 | 155.9/160.3 | 164.5/164.9 | 166.5/164.9 | 180/180 |
| (X-axis/Y-axis) | | | | | |

| | | |
|---|---|---|
| H/P | 0.47 | 0.31 |

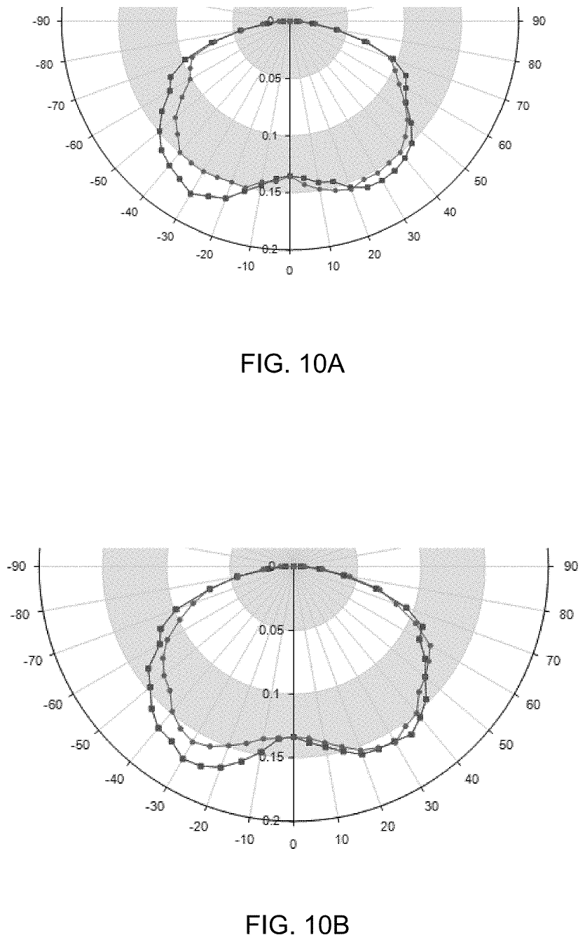

Through the simulation of the software, viewing angles and radiation patterns of various types of lighting devices can also be appreciated. Because the LED die used for simulation and the LED die used for the above measurement are of different types, the viewing angles derived from the above LED dies are not exactly the same. Referring to FIG. 10A and FIG. 10B, the following parameters are used for simulation: the size of the lead frame structure is 3 mm×3 mm×0.25 mm; the thickness of the light-transmissive encapsulant and the light-transmissive wall is 0.55 mm; the refractive index of the light-transmissive encapsulant is 1.4 to 1.5, the refractive index of the light-transmissive wall is 1.4 to 1.6; and the top surface of the light-transmissive encapsulant is a flat surface (similar to the lighting device of FIG. 1A). When the lighting device has a single LED die (single-die), the viewing angle thereof (X-axis/Y-axis) is 142/144 degrees, and the radiation pattern is as shown in FIG. 10A. When the lighting device has two LED dies (double-die), the viewing angle thereof (X-axis/Y-axis) is 143/142 degrees, and the radiation pattern is as shown in FIG. 10B.

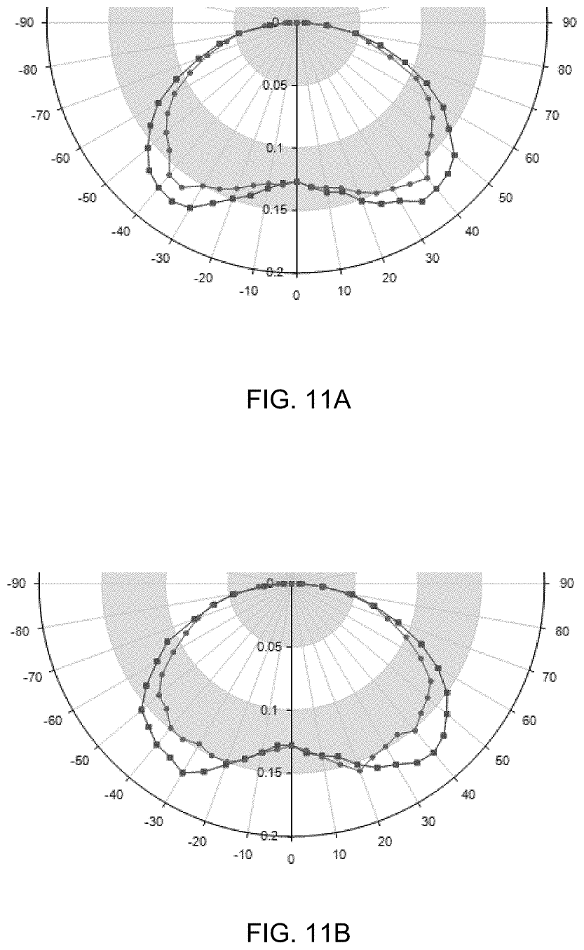

If the thickness of the light-transmissive encapsulant and the light-transmissive wall is reduced to 0.35 mm, and the remaining parameters are as described above, the viewing angle (X-axis/Y-axis) of the single-die case is 139/138 degrees, and the radiation pattern is as shown in FIG. 11A; the viewing angle (X-axis/Y-axis) of the double-die case is 138/139 degrees, and the radiation pattern is as shown in FIG. 11B. As can be known from the above description, the radiation pattern is closer to batwing when the thickness of the light-transmissive encapsulant is reduced.

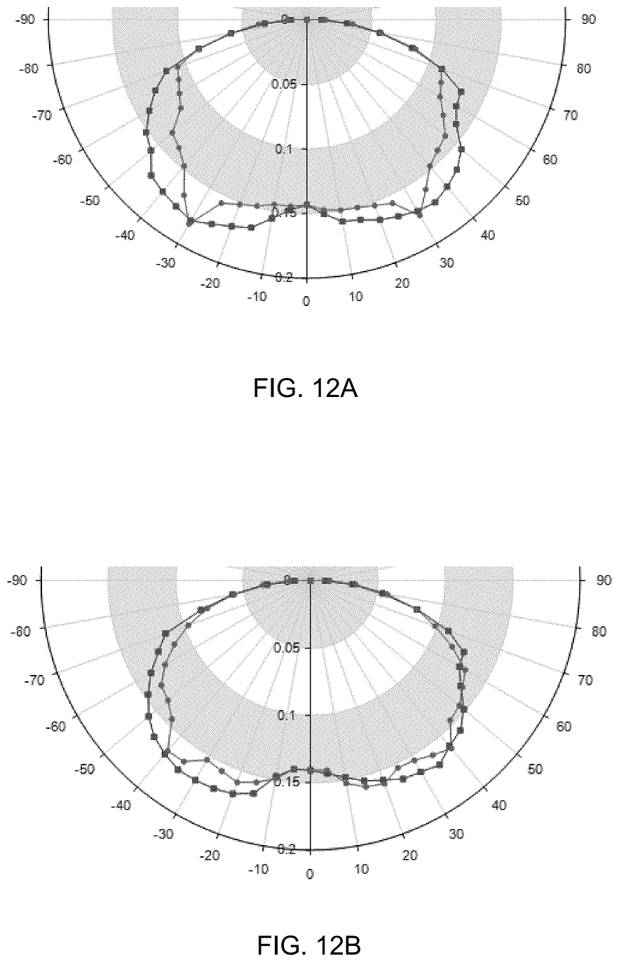

If the top surface of the light-transmissive encapsulant is a convex surface (similar to the lighting device of FIG. 3A), the thickness of the light-transmissive encapsulant is 0.6 mm, the thickness of the light-transmissive wall is 0.55 mm, and the remaining parameters are as described above, the viewing angle (X-axis/Y-axis) of the single-die case is 148/144 degrees, and the radiation pattern is as shown in FIG. 12A; the viewing angle (X-axis/Y-axis) of the double-die case is 149/147 degrees, and the radiation pattern is as shown in FIG. 12B.

If the light-transmissive encapsulant has a lens and a concave portion (similar to the lighting device of FIG. 7A), the thickness of the light-transmissive encapsulant is 0.99 mm, the thickness of the light-transmissive wall is 0.55 mm, and the remaining parameters are as described above, then the viewing angle (X-axis/Y-axis) of the single-die case is 175/177 degrees, and the radiation pattern is as shown in FIG. 13A; the viewing angle (X-axis/Y-axis) of the double-die case is 130/127 degrees, and the radiation pattern is as shown in FIG. 13B. The radiation pattern is closest to batwing. It shall be additionally appreciated that, in the single-die case, the sharp point of the concave portion may correspond to the center of the light-emitting top surface of the LED die, so the light of the LED die can be effectively diffused outward by the concave portion. In the dual-die case, the sharp point of the concave portion corresponds to a gap between two dies, so the light of the LED die is diffused to a smaller degree, but the angle of the light after being diffused is still larger than the original light angle (increased by about 128 degrees).

If there is a reflective layer, the thickness of the light-transmissive encapsulant and the light-transmissive wall is 0.6 mm, the top surface of the light-transmissive encapsulant is a flat surface (similar to the lighting device of FIG. 8A), and the remaining parameters are as described above, then the viewing angle (X-axis/Y-axis) of the case where the shielding surface is 0.205×0.125 mm is 138/144 degrees, and the radiation pattern is as shown in FIG. 14A; the viewing angle (X-axis/Y-axis) of the case where the shielding surface is 0.41×0.25 mm is 145/144 degrees, and the radiation pattern is as shown in FIG. 14B; the viewing angle (X-axis/Y-axis) of the case where the shielding surface is 0.82×0.5 mm is 144/150 degrees, and the radiation pattern is as shown in FIG. 14C. As can be known from the above description, if the reflective layer has a larger shielding surface, then the viewing angle is larger, and the radiation pattern is closer to batwing.

A measurement result of viewing angles of various types of lighting devices is summarized in the following table.

| | Viewing | |
|---|---|---|
| Corre- | angle | |
| sponding | (X-axis/ | |
| Figure | Y-axis) | Notes |
| FIG. 10A | 142/144 | Single-die, the top surface being a flat surface |
| FIG. 10B | 143/142 | Double-die, the top surface being a flat surface |
| FIG. 11A | 139/138 | Single-die, the top surface being a flat surface, |
| | | thickness being reduced |
| FIG. 11B | 138/139 | Double-die, the top surface being a flat surface, |
| | | thickness being reduced |
| FIG. 12A | 148/144 | Single-die, the top surface being a convex |
| | | surface |
| FIG. 12B | 149/147 | Double-die, the top surface being a convex |
| | | surface |
| FIG. 13A | 175/177 | Single-die, having a lens and a concave portion |
| FIG. 13B | 130/127 | Double-die, having a lens and a concave portion |
| FIG. 14A | 138/144 | Single-die, small shielding surface |
| FIG. 14B | 145/144 | Single-die, middle shielding surface |
| FIG. 14C | 144/150 | Single-die, large shielding surface |

The viewing angle describe above is defined according to the Full Width at Half Maximum (FWHM) of the radiation pattern, taking FIG. 10A as an example, the maximum intensity of the radiation pattern shown is 0.17 on the X-axis, and the half value of the maximum intensity is 0.875, the maximum angle corresponding to the half value on the X-axis is about −70 degrees and 72 degrees, so the viewing angle on the X-axis may be calculated as 142 degrees. Similarly, the viewing angle on the X-axis and the Y-axis in FIG. 10A to FIG. 14C can be obtained.

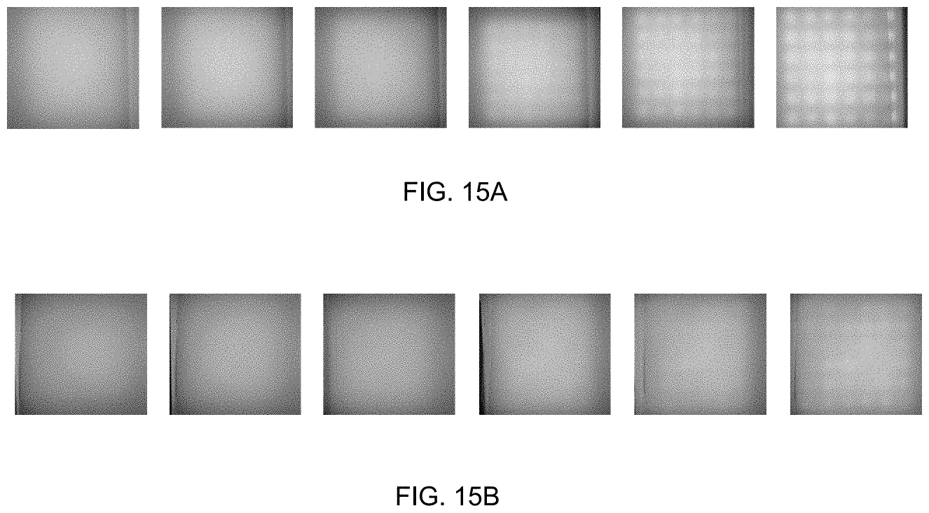

Next, referring to FIG. 15A and FIG. 15B, the conventional lighting device and the lighting device of the present invention are all arranged on the circuit substrate with a lateral distance of 8.5 mm, and light-mixing effects at different vertical distances are tested respectively (the light-mixing effects from left to right are respectively the light-mixing effects at 10 mm, 8 mm, 6 mm, 4 mm, 3 mm and 2 mm). As shown in FIG. 15A, when the vertical distance is 6 mm, the profile of the conventional lighting device is already observable, which means that the light is not mixed uniformly. As shown in FIG. 15B, the profile of the lighting device of the present invention can be seen only when the vertical distance is 3 mm. As can be known from the above description, when the lighting module is constituted by the lighting devices of the present invention, a uniform light-mixing effect can be achieved with a smaller vertical distance.

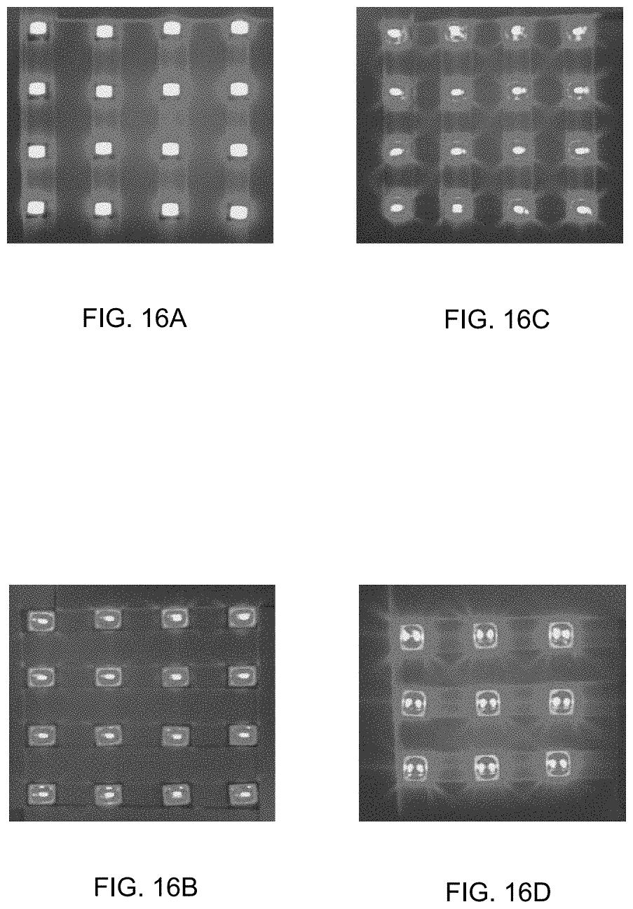

Further referring to FIG. 16A to FIG. 16D, the shape of the light spot of the conventional lighting device corresponds to the profile of the reflector cup (FIG. 16A, FIG. 16B), and the light spot of the lighting device of the present invention has a special shape, and arrows in a radial pattern can be observed (FIG. 16C and FIG. 16D). As can be known from the above description, the lighting device of the present invention can also provide illumination of a special light-spot shape in addition to providing illumination of a larger viewing angle.

In an embodiment, the light emitted from the LED die may be ultraviolet (for example, UVC, UVB, UVA), blue light or blue-green light. In an embodiment, the LED die comprises an N-type semiconductor layer, an active layer and a P-type semiconductor layer, the active layer is interposed between the N-type semiconductor layer and the P-type semiconductor layer, and the active layer may be a multiple quantum-well layer. In an embodiment, the LED die can be replaced by a laser diode die, and the light emitted by the laser diode may be ultraviolet (for example, UVC, UVB, UVA), blue light or blue-green light. In an embodiment, the laser diode die comprises an N-type semiconductor layer, an active layer and a P-type semiconductor layer, the active layer is interposed between the N-type semiconductor layer and the P-type semiconductor layer, and the active layer may be a multiple quantum-well layer.

In an embodiment, the light-transmissive encapsulant may comprise a first photoluminescence material, the first photoluminescence material may absorb the light of the LED die to emit a light having a first wavelength, but the light-transmissive wall does not comprise any photoluminescence material. The concentration of the first photoluminescence material may be uniform, or the concentration of the first photoluminescence material is gradually reduced or increased in the direction from the top surface of the light-transmissive encapsulant to the top surface of the LED die.

In an embodiment, the light-transmissive wall may comprise a first photoluminescence material, the first photoluminescence material may absorb the light of the LED die to emit a light having a first wavelength, but the light-transmissive encapsulant does not comprise any photoluminescence material. The concentration of the first photoluminescence material may be uniform, or the concentration of the first photoluminescence material is gradually reduced or increased in the direction from the external side surface of the light-transmissive wall to the LED die.

In an embodiment, the light-transmissive encapsulant may comprise a first photoluminescence material and a second photoluminescence material, the first photoluminescence material may absorb the light of the LED die to emit a light having a first wavelength. The light-transmissive wall may comprise a second photoluminescence material, and the second photoluminescence material may absorb the light of the LED die to emit a light having a second wavelength. The concentration of the first photoluminescence material may be uniform, or the concentration of the first photoluminescence material is gradually reduced or increased in the direction from the top surface of the light-transmissive encapsulant to the top surface of the LED die. The concentration of the second photoluminescence material may be uniform, or the concentration of the second photoluminescence material is gradually reduced or increased in the direction from the external side surface of the light-transmissive wall to the LED die.

In an embodiment, the light-transmissive encapsulant may comprise a first photoluminescence material and a second photoluminescence material, but the light-transmissive wall does not comprise any photoluminescence material. The first photoluminescence material may be distributed above the LED die, and the second photoluminescence material may be distributed at the periphery of the side surface of the LED die. The concentration of the first photoluminescence material and the second photoluminescence material may be uniform, or the concentration of the first photoluminescence material and the second photoluminescence material is gradually reduced or increased in the direction from the top surface of the light-transmissive encapsulant to the top surface of the LED die.

In an embodiment, the light-transmissive wall may comprise a first photoluminescence material and a second photoluminescence material, but the light-transmissive encapsulant does not comprise any photoluminescence material. The concentration of the first photoluminescence material and the second photoluminescence material may be uniform, or the concentration of the first photoluminescence material and the second photoluminescence material is gradually reduced or increased in the direction from the external side surface of the light-transmissive wall to the LED die.

The first wavelength may be the same as or different from the second wavelength. The first wavelength may be less than or larger than the second wavelength. The first and second photoluminescence materials may be any combination of yellow fluorescent powder, green fluorescent powder and red fluorescent powder. The yellow fluorescent powder may be Y₃Al₅O₁₂: Ce³⁺ (called for short as YAG) and (Sr, Ba)₂SiO₄: Eu²⁺ (the content of Sr²⁺ is higher, called for short as Silicate), the green fluorescent powder may be Si_{6-z}Al_{z}O_{z}N_{8-z}:Eu²⁺ (called for short as β-SiAlON) and Lu₃Al₅O₁₂:Ce³⁺ (called for short as LuAG), the red fluorescent powder may be CaAlSiN₃:Eu²⁺ (called for short as CASN or 1113), Sr₂Si₅N₈:Eu²⁺ (called for short as 258) and K₂SiF₆:Mn⁴⁺ (called for short as KSF).

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A lighting device, comprising:
an LED die, comprising a light-emitting top surface and a plurality of light-emitting side surfaces, the light-emitting top surface being connected with the light-emitting side surfaces;
a light-transmissive encapsulant, covering the light-emitting side surfaces and the light-emitting top surface of the LED die, and comprising a plurality of side surfaces connected with each other, a top surface and a bottom surface; and
a light-transmissive wall, surrounding the light-transmissive encapsulant and covering the side surfaces of the light-transmissive encapsulant, wherein a refractive index of the light-transmissive encapsulant is not greater than a refractive index of the light-transmissive wall.

2. The lighting device of claim 1, wherein an angle is defined between the side surface and the bottom surface, and the angle ranges from 90 degrees to 160 degrees.

3. The lighting device of claim 1, wherein the light-transmissive wall comprises a filling material for increasing the structural strength.

4. The lighting device of claim 1, wherein the light-transmissive encapsulant comprises a photoluminescence material.

5. The lighting device of claim 1, wherein the top surface of the light-transmissive encapsulant is selected from the group consisting of a flat surface, a concave surface, a convex surface and any combination thereof.

6. The lighting device of claim 1, wherein the light-transmissive encapsulant further comprises a lens, and the lens comprises a concave portion.

7. The lighting device of claim 1, further comprising a reflective layer, wherein the reflective layer is located above the light-emitting top surface of the LED die, and shields the light-emitting top surface in a normal direction of the light-emitting top surface.

8. The lighting device of claim 7, wherein the reflective layer is disposed on the top surface of the light-transmissive encapsulant or disposed on the light-emitting top surface of the LED die.

9. The lighting device of claim 7, wherein the reflective layer includes a shielding surface, and the shielding surface is not less than the light-emitting top surface of the LED die or not less than the top surface of the light-transmissive encapsulant.

10. The lighting device of claim 9, wherein the shielding surface is of a circular shape, an elliptical shape or a polygonal shape.

11. The lighting device of claim 9, wherein the shielding surface comprises a plurality of light-transmissive regions.

12. The lighting device of claim 1, further comprising another LED die, wherein the light-transmissive encapsulant covers a plurality of light-emitting side surfaces and a light-emitting top surface of the another LED die.

13. The lighting device of claim 1, further comprising a lead frame structure, wherein the LED die is disposed on the lead frame structure and is electrically connected with the lead frame structure, while the light-transmissive encapsulant and the light-transmissive wall are disposed on the lead frame structure.

14. The lighting device of claim 1, further comprising a carrier substrate, wherein the LED die is disposed on the carrier substrate and electrically connected with the carrier substrate, while the light-transmissive encapsulant and the light-transmissive wall are disposed on the carrier substrate.

15. The lighting device of claim 1, wherein any of the light-transmissive encapsulant and the light-transmissive wall comprises a thermoplastic resin or a thermosetting resin.

16. A lighting module, comprising:
a circuit substrate;
a plurality of lighting devices of claim 1, the lighting devices being disposed on the circuit substrate and electrically connected with the circuit substrate.

17. The lighting module of claim 16, further comprising a light diffuser plate, wherein the light diffuser plate is disposed above the lighting devices.

18. The lighting module of claim 17, wherein in a normal direction of the light-emitting top surface of the LED die of the lighting device, there is a vertical distance between the light diffuser plate and the circuit substrate, and in a lateral direction that is orthogonal to the normal direction, there is a lateral distance between the lighting devices; and a ratio of the vertical distance to the lateral distance ranges from 0.1 to 0.8.
